(19) United States
(12) Patent Application Publication
(10) Pub. No.: US 2014/0144684 A1
(43) Pub. Date: May 29, 2014

(54) CONDUCTIVE PATTERN AND METHOD FOR PRODUCING THE SAME

(71) Applicants: Yukie Saitou, Osaka (JP); Wataru Fujikawa, Osaka (JP); Jun Shirakami, Osaka (JP)

(72) Inventors: Yukie Saitou, Osaka (JP); Wataru Fujikawa, Osaka (JP); Jun Shirakami, Osaka (JP)

(73) Assignee: DIC CORPORATION, Tokyo (JP)

(21) Appl. No.: 14/234,191

(22) PCT Filed: Jun. 22, 2012
(86) PCT No.: PCT/JP2012/065951

§ 371 Date: Jan. 22, 2014

(30) Foreign Application Priority Data
Jul. 22, 2011 (JP) 2011-160871

(51) Int. Cl. H05K 1/09; H05K 3/12

(52) U.S. Cl. CPC H05K 1/095; H05K 3/1283
USPC 174/257; 427/98.5

(57) ABSTRACT

The present invention relates to a conductive pattern including a layer (A) including a substrate, an absorbing layer (B), and a conductive layer (C). The absorbing layer (B) is formed by applying conductive ink containing a conductive substance (c) that constitutes the conductive layer (C) to a surface of a resin layer (B1) including a vinyl resin (b1) produced by polymerizing a monomer mixture containing 10% by mass to 70% by mass of methyl (meth)acrylate; and subsequently forming crosslinks in the resin layer (B1).

### TECHNICAL FIELD

The present invention relates to a conductive pattern that can be used as an electric circuit or the like and a method for producing the conductive pattern.

### BACKGROUND ART

Recently, in the rapidly-growing industries related to inkjet printing, there have been dramatic advances in the improvement of the performance of inkjet printers, modifications of ink, and the like. As a result, high-definition, sharp images having high print quality, which are comparable to silver halide photos, will become readily available even in the home. Thus, as well as home-use, use of inkjet printers in the manufacturing of billboards or the like is now being studied.

Use of the inkjet printing technique in the manufacturing of electronic circuits or the like is also being studied. This is because, recently, there have been demands for improvement of function, reduction in size, and reduction in thickness in electronic devices and accordingly there have been also strong demands for increase in density and reduction in thickness in electronic circuits and integrated circuits that are used in the electronic devices.

An example of a method for producing a conductive pattern such as an electronic circuit using the inkjet printing technique is a method in which conductive ink containing a conductive substance such as silver is printed on a substrate by an inkjet printing method to form a conductive pattern such as an electronic circuit.

Specifically, a method for forming a conductive pattern by drawing a pattern on an ink absorbing substrate including a latex layer using conductive ink by a predetermined method is known. It is known that an acrylic resin can be used as the latex layer (see PTL 1).

However, this conductive-ink absorbing layer including the latex layer, which constitutes the conductive pattern, may cause, for example, bleeding of the conductive ink. This may lead to difficulty in forming fine conducting lines having a width of about 0.01 μm to 200 μm, which is generally required in order to realize high-density electronic circuits and the like.

When a conductive pattern is formed, the surface of the conductive pattern is usually subjected to a plating process in order to improve conductivity.

Chemical agents for plating used in the plating process and chemical agents used in a cleaning step of the plating process are generally highly alkaline or highly acidic. Therefore, use of these chemical agents may cause, for example, a conductive pattern and a conductive-ink absorbing layer or the like of the conductive pattern to be dissolved, which may result in, for example, a break in the conducting lines.

Thus, there is a demand for conductive patterns having a characteristic of being formed of fine lines and durability such that the conductive-ink absorbing layer is prevented from being dissolved even when the conductive pattern is immersed in the chemical agent repeatedly over a prolonged period of time.

### CITATION LIST

### Patent Literature

PTL 1: Japanese Unexamined Patent Application Publication No. 2009-49124

### SUMMARY OF INVENTION

### Technical Problem

An object of the present invention is to form a conductive pattern having an excellent characteristic of being formed of fine lines and excellent durability such that the conductive pattern can maintain good conductivity without, for example, a conductive-ink absorbing layer being dissolved and removed even when, for example, a solvent such as a chemical agent for plating or a cleaning agent is adhered to the conductive pattern.

### Solution to Problem

The inventors of the present invention have conducted studies in order to address the problems and, as a result, have found that the problems of the present invention can be addressed by applying conductive ink to a conductive-ink absorbing substrate including a conductive-ink absorbing layer having a specific composition and subsequently forming a crosslinked structure in the conductive-ink absorbing layer.

Specifically, the present invention provides a conductive pattern including a layer (A) including a substrate, an absorbing layer (B), and a conductive layer (C).

The absorbing layer (B) is formed by applying conductive ink containing a conductive substance (c) that constitutes the conductive layer (C) to a surface of a resin layer (B1) including a vinyl resin (b1) produced by polymerizing a monomer mixture containing 10% by mass to 70% by mass of methyl (meth)acrylate; and subsequently forming crosslinks in the resin layer (B1).

The present invention also provides a method for producing a conductive pattern that includes a layer (A) including a substrate, an absorbing layer (B), and a conductive layer (C),

the method including forming a resin layer (B1) by applying a resin composition for forming an absorbing layer to a portion or the entirety of a surface of the substrate and drying the resin composition, the resin composition including a vinyl resin (b1) produced by polymerizing a monomer mixture containing 10% by mass to 70% by mass of methyl (meth)acrylate; subsequently applying conductive ink containing a conductive substance (c) to a portion or the entirety of a surface of the resin layer (B1); and heating the resin layer (B1) to cause a crosslinking reaction and thereby forming the absorbing layer (B) having a crosslinked structure.

### Advantageous Effects of Invention

The conductive pattern according to the present invention has an excellent characteristic of being formed of fine lines and durability such that the conductive pattern can maintain good conductivity without, for example, a conductive-ink absorbing layer being dissolved and removed even when, for example, a solvent such as a chemical agent for plating or a cleaning agent is adhered to the conductive pattern. Thus, the conductive pattern according to the present invention may be used in a new field generally referred to as printed electronics, such as formation of electronic circuit using, for example, conductive ink containing a conductive substance such as silver; formation of layers constituting an organic solar cell, an electronic book reader, an organic EL, an organic transistor, a flexible printed substrate, RFID such as a contactless IC card, or the like and their peripheral wires; wiring in an electromagnetic shielding of a plasma display; and the manufacturing of an integrated circuit, an organic transistor, and the like.

### DESCRIPTION OF EMBODIMENTS

A conductive pattern according to the present invention includes a layer (A) including a substrate, an absorbing layer (B), and a conductive layer (C). The absorbing layer (B) is formed by applying conductive ink containing a conductive substance (c) that constitutes the conductive layer (C) to a surface of a resin layer (B1) including a vinyl resin (b1) produced by polymerizing a monomer mixture containing 10% by mass to 70% by mass of methyl (meth)acrylate; and subsequently forming crosslinks in the resin layer (B1). The term “methyl (meth)acrylate” herein refers to either of or both methyl acrylate and methyl methacrylate.

The conductive pattern according to the present invention includes the layer (A) including a substrate, the absorbing layer (B), and the conductive layer (C).

The absorbing layer (B) constituting the conductive pattern may be formed over a portion or the entirety of the surface of the layer (A) including a substrate and may be formed on either of or both the surface and the backside of the layer (A) including a substrate.

For example, the conductive pattern may be formed by forming the resin layer (B1), which is to be formed into the absorbing layer (B), over the entire surface of the substrate; then applying (printing) conductive ink to a desired portion of the surface of the resin layer (B1); and subsequently forming crosslinks in the resin layer (B1) and thereby forming the absorbing layer (B) and the conductive layer (C) including the conductive substance (c).

The absorbing layer (B) may be formed only on a portion of the surface of the substrate on which the conductive layer (C) is to be formed.

The conductive pattern according to the present invention may include another layer between the layer (A) including a substrate and the absorbing layer (B) or between the absorbing layer (B) and the conductive layer (C). However, the absorbing layer (B) is preferably formed on the surface of the layer (A), and the conductive layer (C) is preferably formed on the surface of the absorbing layer (B). As needed, the conductive pattern according to the present invention may include a plating layer (D) on the surface of the conductive layer (C).

The conductive pattern can be produced through the following steps: Step (1) of forming a conductive-ink absorbing substrate including a resin layer (B1), which is to be formed into an absorbing layer (B), over a portion or the entirety of the surface of a substrate that is to be formed into the layer (A); Step (2) of applying conductive ink containing a conductive substance (c) to the conductive-ink absorbing substrate; and Step (3) of forming an absorbing layer (B) by, for example, heating the coated item prepared in Step (2) and thereby forming a crosslinked structure in the resin layer (B1).

First, Step (1) will be described.

In Step (1), a conductive-ink absorbing substrate including a resin layer (B1), which is formed into the absorbing layer (B), is formed over a portion or the entirety of the surface of a substrate.

Examples of the substrate include a substrate and a porous substrate that are composed of a polyimide resin, a polyamide-imide resin, a polyamide resin, poly(ethylene terephthalate), poly(ethylene naphthalate), polycarbonate, acrylonitrile-butadiene-styrene (ABS), an acrylic resin such as poly[methyl (meth)acrylate], poly(vinylidene fluoride), poly(vinyl chloride), poly(vinylidene chloride), poly(vinyl alcohol), polyethylene, polypropylene, polyurethane, cellulose nanofiber, silicon, ceramic, or glass.

In particular, the substrate is preferably a substrate composed of a polyimide resin, poly(ethylene terephthalate), poly(ethylene naphthalate), glass, cellulose nanofiber, or the like, which are commonly used as a substrate in forming a conductive pattern such as a circuit substrate.

When the substrate is used for, for example, a purpose that requires the flexibility of the conductive pattern, a relatively flexible substrate capable of, for example, being easily bent is preferably used as the substrate in order to impart flexibility to the conductive pattern and thus produce an end item capable of being bent. Specifically, a film-like or sheet-like substrate formed by uniaxial stretching or the like is preferably used.

Examples of the film-like or sheet-like substrate include a poly(ethylene terephthalate) film, a polyimide film, and a poly(ethylene naphthalate) film.

The substrate preferably has a thickness of about 1 μm to 200 μm in order to realize reductions in weight and thickness of the conductive pattern and the end item in which the conductive pattern is used.

The resin layer (B1) formed over a portion or the entirety of the surface of the substrate includes the vinyl resin (A) and, as needed, other additives.

The resin layer (B1) formed on the conductive-ink absorbing substrate is a resin layer in which no crosslinked structure is substantially formed prior to the application of the conductive ink in Step (2). A resin layer in which “no crosslinked structure is substantially formed” refers to a resin layer in which no crosslinked structure is formed at all or a resin layer in which about 5% or less of the functional groups that are concerned with formation of the crosslink structure partially form a crosslinked structure.

Thus, the conductive ink is applied to the surface of the resin layer (B1) in which no crosslinked structure is substantially formed, and subsequently the coated surface is subjected to heating, photoirradiation, or the like to form a crosslinked structure in the resin layer (B1). This imparts durability such that the conductive pattern can maintain good conductivity without, for example, the absorbing layer (B) being dissolved and removed from the substrate even when, for example, a solvent such as a chemical agent for plating or a cleaning agent is adhered to the conductive pattern.

The resin layer (B1) includes a vinyl resin (b1) prepared by polymerizing a monomer mixture containing 10% by mass to 70% by mass of methyl (meth)acrylate and, as needed, other additives.

The resin layer (B1) can be formed by applying a resin composition for forming an absorbing layer including the vinyl resin (b1) to a desired portion of the substrate and drying the resin composition.

The resin composition for forming an absorbing layer that can be used for forming the resin layer (B1) hardly causes a crosslinking reaction and thus no crosslinked structure is substantially formed in the step of forming the resin layer (B1) on the surface of the substrate. However, a crosslinking reaction rapidly proceeds through the step of heating, photoirradiation, or the like after application of the conductive ink, and thereby the resin composition for forming an absorbing layer forms the absorbing layer (B) in which a crosslinked structure is formed.

The resin composition for forming an absorbing layer includes, for example, a vinyl resin (b1) prepared by polymerizing a vinyl monomer mixture containing 10% by mass to 70% by mass of methyl (meth)acrylate relative to the total amount of the vinyl monomer mixture and, as needed, a crosslinking agent (b2), a solvent such as water or an organic solvent, and other additives.

If a vinyl resin prepared by polymerizing a vinyl monomer mixture containing 5% by mass of methyl (meth)acrylate is used instead of the vinyl resin (b1), bleeding of a printed portion such as above-described fine lines is likely to be caused, which may result in degradation of the characteristic of being formed of fine lines. In addition, adhesion between the conductive ink and the conductive-ink absorbing layer may be reduced.

If a vinyl resin prepared by polymerizing a vinyl monomer containing 80% by mass of methyl (meth)acrylate is used instead of the vinyl resin (b1), for example, the characteristic of being formed of fine lines may be degraded.

Thus, the vinyl resin (b1) is preferably a vinyl resin produced by polymerizing a vinyl monomer mixture containing 40% by mass to 65% by mass of methyl (meth)acrylate and more preferably a vinyl resin prepared by polymerizing a vinyl monomer mixture containing 50% by mass to 65% by mass of methyl (meth)acrylate relative to the total amount of the vinyl monomer mixture.

The vinyl resin (b1) preferably has a weight-average molecular weight of 100,000 or more in order to impart a remarkable characteristic of being formed of fine lines.

When the vinyl resin (b1) and an organic solvent are used in combination as the resin composition for forming an absorbing layer, the vinyl resin (b1) preferably has a weight-average molecular weight of 100,000 to 1,000,000.

When the vinyl resin (b1) and an aqueous medium are used in combination as the resin composition for forming an absorbing layer, the vinyl resin (b1) preferably has a weight-average molecular weight of 1,000,000 or more.

The upper limit of the weight-average molecular weight of the vinyl resin (b1) is not particularly set but is preferably set to about 10,000,000 or less and preferably set to 5,000,000 or less. The vinyl resin (b1) having the above-described molecular weight is preferably also used to form the absorbing layer (B) for conductive ink with which no bleeding occurs when the absorbing layer (B) is used for forming a conductive pattern and thereby an excellent characteristic of being formed of fine lines can be realized.

The weight-average molecular weight of the vinyl resin (b1) can be determined by gel permeation chromatography method (GPC) with a measurement sample prepared by mixing 80 mg of the vinyl resin (b1) and 20 ml of tetrahydrofuran and stirring the mixture for 12 hours. A measurement apparatus may be a high-performance liquid chromatograph “HLC-8220” produced by TOSOH CORPORATION. Columns may be TSKgelGMH XL×4 columns. An eluent may be tetrahydrofuran. A detector may be an R1 detector.

However, when the molecular weight of the vinyl resin (b1) exceeds about 1,000,000, it may be difficult to determine the molecular weight of the vinyl resin (b1) by a general molecular-weight determining method using GPC or the like.

Specifically, even when 80 mg of the vinyl resin (b1) having a weight-average molecular weight exceeding 1,000,000 is mixed with 20 ml of tetrahydrofuran and the liquid mixture is stirred for 12 hours, the vinyl resin (b1) may fail to be dissolved completely and, when the liquid mixture is filtered through a 1-μm membrane filter, a residue derived from the vinyl resin (b1) may be observed on the membrane filter.

Since such a residue is derived from a vinyl resin having a molecular weight exceeding about 1,000,000, it may be difficult to determine the right weight-average molecular weight by GPC with a filtrate obtained by the filtration.

Thus, in the present invention, when a residue is observed on the membrane filter as a result of the filtration, the vinyl resin is considered to have a weight-average molecular weight exceeding 1,000,000.

The vinyl resin (b1) preferably has a hydrophilic group such as an anionic group so that, when the solvent is an aqueous medium, good water dispersibility in the aqueous medium is imparted to the vinyl resin.

The anionic group may be a carboxyl group, a sulfonic group, and a carboxylate group or a sulfonate group formed by neutralizing a carboxyl group or a sulfonic group using a neutralizing agent that is a basic compound such as a basic metal compound or a basic nonmetal compound.

The anionic group such as a carboxyl group may serve as a crosslinking point of the crosslinking agent (D) described below when the absorbing layer (B) is formed.

Examples of the neutralizing agent include basic metal compounds such as sodium hydroxide, potassium hydroxide, calcium hydroxide, and calcium carbonate; ammonia; and basic nonmetal compounds such as monomethylamine, dimethylamine, trimethylamine, monoethylamine, diethylamine, triethylamine, monopropylamine, dimethylpropylamine, monoethanolamine, diethanolamine, triethanolamine, ethylenediamine, and diethylenetriamine.

The carboxyl group and the like may be present as the above-described hydrophilic group and as the crosslinkable functional group described below in the vinyl resin (b1). The carboxyl group and the like is preferably introduced in the vinyl resin (b1) so that the vinyl resin (b1) has an acid value of 0 to 10 and preferably 0.5 to 5 in order to produce a conductive pattern having excellent durability.

The vinyl resin (b1) may be a vinyl resin having a crosslinkable functional group in order to form the absorbing layer (B) having a crosslinked structure by, for example, heating. The crosslinkable functional group may cause a crosslinking reaction with another crosslinkable functional group of the vinyl resin to form a crosslinked structure. When the vinyl resin (b1) and the crosslinking agent (D) are used in combination as the resin composition for forming an absorbing layer, the crosslinkable functional group may react with a functional group of the crosslinking agent (D) to form a crosslinked structure.

The crosslinkable functional group that may be included in the vinyl resin (b1) causes a crosslinking reaction by being heated or the like after the conductive ink is applied (printed) to the conductive-ink absorbing substrate, and thereby the absorbing layer (B) having a crosslinked structure is formed. This allows formation of a conductive pattern having excellent durability such that the conductive pattern can maintain good conductivity without, for example, the absorbing layer (B) being dissolved and removed from the substrate even when, for example, a solvent such as a chemical agent for plating or a cleaning agent is adhered to the conductive pattern.

The crosslinkable functional group is preferably capable of causing a crosslinking reaction by, for example, being heated to about 100° C. or more and thereby forming the crosslinked structure. Specifically, at least one thermal-crosslinkable functional group selected from the group consisting of a methylolamide group and an alkoxymethylamide group is preferably used.

Specific examples of the alkoxymethylamide group include amide groups having a methoxymethyl group, an ethoxymethyl group, a propoxymethyl group, a butoxymethyl group, or the like attached to the nitrogen atom.

When the resin composition for forming an absorbing layer includes the crosslinking agent (b2), the vinyl resin (b1) is preferably a vinyl resin having a functional group such as a hydroxyl group or a carboxyl group. An amino group may also be used when the conditions for forming the absorbing layer (B) are fully controllable.

The vinyl resin (b1) preferably has a glass-transition temperature of 1° C. to 70° C. in order to produce a conductive pattern having an excellent characteristic of being formed of fine lines. The vinyl resin (b1) preferably has a glass-transition temperature of 10° C. to 40° C. in order to impart a good film-forming property for forming the absorbing layer (B) and blocking resistance such that, when the conductive-ink absorbing substrate is stacked on the layer (A), adhesion between the absorbing layer (B) constituting the ink absorbing substrate and the backside of the layer (A) including a substrate constituting the ink absorbing substrate over time is prevented from occurring.

The vinyl resin (b1) may be produced by, for example, radical polymerization of a vinyl monomer mixture including 10% by mass to 70% by mass of methyl (meth)acrylate and, as needed, other vinyl monomers such as a vinyl monomer having a crosslinkable functional group.

Examples of the vinyl monomer having a crosslinkable functional group include vinyl monomers having a crosslinkable functional group such as at least one amide group selected from the group consisting of a methylolamide group and an alkoxymethylamide group, an amide group other than the above-described amide group, a hydroxyl group, a glycidyl group, an amino group, a silyl group, an aziridinyl group, an isocyanate group, an oxazoline group, a cyclopentenyl group, an allyl group, a carbonyl group, or an acetoacetyl group.

Examples of the vinyl monomer having at least one amide group selected from the group consisting of a methylolamide group and an alkoxymethylamide group, which can be used as the vinyl monomer having the crosslinkable functional group, include N-methylol(meth)acrylamide, N-methoxymethyl(meth)acrylamide, N-ethoxymethyl(meth)acrylamide, N-propoxymethyl(meth)acrylamide, N-isopropoxymethyl(meth)acrylamide, N-n-butoxymethyl(meth)acrylamide, N-isobutoxymethyl(meth)acrylamide, N-penthoxymethyl(meth)acrylamide, N-ethoxymethyl-N-methoxymethyl(meth)acrylamide, N,N′-dimethylol(meth)acrylamide, N-ethoxymethyl-N-propoxymethyl(meth)acrylamide, N,N′-dipropoxymethyl(meth)acrylamide, N-butoxymethyl-N-propoxymethyl(meth)acrylamide, N,N-dibutoxymethyl(meth)acrylamide, N-butoxymethyl-N-methoxymethyl(meth)acrylamide, N,N′-dipenthoxymethyl(meth)acrylamide, and N-methoxymethyl-N-penthoxymethyl(meth)acrylamide. The term “(meth)acryl” herein refers to either of or both “acryl” and “methacryl”. The same is true for the term “(meth)acrylate”.

In particular, N-n-butoxymethyl(meth)acrylamide and N-isobutoxymethyl(meth)acrylamide are preferably used in order to form a conductive pattern having an excellent characteristic of being formed of fine lines and excellent durability such that the conductive pattern can maintain good conductivity without, for example, the absorbing layer (B) being dissolved and removed from the substrate even when, for example, a solvent such as a chemical agent for plating or a cleaning agent is adhered to the conductive pattern.

Examples of the vinyl monomer having a crosslinkable functional group include, in addition to the above-described vinyl monomers, vinyl monomers having an amide group, such as (meth)acrylamide; vinyl monomers having a hydroxyl group, such as 2-hydroxyethyl (meth)acrylate, 2-hydroxypropyl (meth)acrylate, 2-hydroxybutyl (meth)acrylate, 4-hydroxybutyl (meth)acrylate, 6-hydroxyhexyl (meth)acrylate, (4-hydroxymethylcyclohexyl)methyl (meth)acrylate, glycerol (meth)acrylate, polyethylene glycol (meth)acrylate, and N-hydroxyethyl(meth)acrylamide; polymerizable monomers having a glycidyl group, such as glycidyl (meth)acrylate and (meth)acrylic acid allyl glycidyl ether; polymerizable monomers having an amino group, such as aminoethyl (meth)acrylate, an N-monoalkylaminoalkyl (meth)acrylate, and an N,N-dialkylaminoalkyl (meth)acrylate; polymerizable monomers having a silyl group, such as vinyltrichlorosilane, vinyltrimethoxysilane, vinyltriethoxysilane, vinyltris(β-methoxyethoxy)silane, γ-(meth)acryloxypropyltrimethoxysilane, γ-(meth)acryloxypropyltriethoxysilane, γ-(meth)acryloxypropylmethyldimethoxysilane, γ-(meth)acryloxypropylmethyldiethoxysilane, γ-(meth)acryloxypropyltriisopropoxysilane, N-β-(N-vinylbenzylaminoethyl)-γ-aminopropyltrimethoxysilane, or a hydrochloride thereof; polymerizable monomers having a aziridinyl group, such as 2-aziridinylethyl (meth)acrylate; polymerizable monomer having an isocyanate group and/or a blocked isocyanate group, such as a phenol-adduct and a methyl ethyl ketoxime adduct of (meth)acryloyl isocyanate or (meth)acryloyl isocyanatoethyl; polymerizable monomers having an oxazoline group, such as 2-isopropenyl-2-oxazoline and 2-vinyl-2-oxazoline; polymerizable monomers having a cyclopentenyl group, such as dicyclopentenyl (meth)acrylate; polymerizable monomers having an allyl group, such as allyl (meth)acrylate; polymerizable monomers having a carbonyl group, such as acrolein and diacetone(meth)acrylamide; polymerizable monomers having an acetoacetyl group, such as acetoacetoxyethyl (meth)acrylate; and vinyl monomers having an acid group, such as acrylic acid, methacrylic acid, β-carboxyethyl (meth)acrylate, 2-(meth)acryloyl propionic acid, crotonic acid, itaconic acid, maleic acid, fumaric acid, a half ester of itaconic acid, a half ester of maleic acid, maleic anhydride, and itaconic anhydride.

N-butoxymethyl(meth)acrylamide and N-isobutoxymethyl(meth)acrylamide, which are capable of causing a self-crosslinking reaction by, for example, being heated as described above, are preferably used as the vinyl monomer having a crosslinkable functional group alone or in combination with a vinyl monomer having a hydroxyl group, such as (meth)acrylamide, 2-hydroxyethyl (meth)acrylate, or 4-hydroxybutyl (meth)acrylate described above.

The vinyl monomer having a crosslinkable functional group is preferably N-butoxymethyl(meth)acrylamide in order to improve the durability of the conductive pattern.

When the crosslinking agent (b2) described below is used, 2-hydroxyethyl (meth)acrylate, 2-hydroxypropyl (meth)acrylate, or 4-hydroxybutyl (meth)acrylate is preferably used in order to introduce a functional group that can serve as a crosslinking point of the crosslinking agent (b2), such as a hydroxyl group, to the vinyl resin (b1). The vinyl monomer having a hydroxyl group is preferably used when the crosslinking agent (b2) described below is an isocyanate crosslinking agent.

The content of the vinyl monomer having a crosslinkable functional group is 0% by mass to 50% by mass of the total amount of the vinyl monomer mixture used for producing the vinyl resin (b1). When the crosslinking agent (b2) causes a self-crosslinking reaction, addition of the vinyl monomer having a crosslinkable functional group may be omitted.

Among the above-described vinyl monomers having a crosslinkable functional group, the content of the vinyl monomer having an amide group is preferably 0.1% by mass to 50% by mass and more preferably 1% by mass to 30% by mass of the total amount of the vinyl monomer mixture used for producing the vinyl resin (b1) in order to introduce a self-crosslinkable methylolamide group or the like.

The content of the vinyl monomer having an amide group other than the amide groups described above and the content of the vinyl monomer having a hydroxyl group, which is used in combination with the self-crosslinkable methylolamide group, is preferably 0.1% by mass to 30% by mass and more preferably 1% by mass to 20% by mass of the total amount of the vinyl monomer mixture used for producing the vinyl resin (b1).

Among the above-described vinyl monomers having a crosslinkable functional group, the content of the vinyl monomer having a hydroxyl group varies depending on, for example, the type of crosslinking agent (b2) used in combination with the vinyl monomer but is generally 0.05% by mass to 50% by mass, preferably 0.05% by mass to 30% by mass, and more preferably 0.1% by mass to 10% by mass of the total amount of the vinyl monomer mixture used for producing the vinyl resin (b1).

More specifically, the equivalence ratio between crosslinkable functional groups in the vinyl resin (b1) and crosslinkable functional groups in the crosslinking agent (b2) [crosslinkable functional groups in the vinyl resin (b1)/crosslinkable functional groups in the crosslinking agent (b2)] is preferably 100/1 to 100/500, more preferably 100/2 to 100/200, and further preferably 100/5 to 100/100.

Examples of other vinyl monomers that can be used for producing the vinyl resin (b1) include (meth)acrylic acid esters such as ethyl (meth)acrylate, n-butyl (meth)acrylate, i-butyl (meth)acrylate, t-butyl (meth)acrylate, 2-ethylhexyl (meth)acrylate, hexyl (meth)acrylate, cyclohexyl (meth)acrylate, octyl (meth)acrylate, nonyl (meth)acrylate, dodecyl (meth)acrylate, stearyl (meth)acrylate, isobornyl (meth)acrylate, dicyclopentanyl (meth)acrylate, phenyl (meth)acrylate, and benzyl (meth)acrylate; and (meth)acrylic acid alkyl esters such as 2,2,2-trifluoroethyl (meth)acrylate, 2,2,3,3-pentafluoropropyl (meth)acrylate, perfluorocyclohexyl (meth)acrylate, 2,2,3,3-tetrafluoropropyl (meth)acrylate, and β-(perfluorooctyl)ethyl (meth)acrylate.

In particular, a (meth)acrylic acid alkyl ester having an alkyl group with a carbon number of 2 to 12 is preferably used in combination with the above-described methyl (meth)acrylate or the like in order to impart an excellent characteristic of being formed of fine lines. An acrylic acid alkyl ester having an alkyl group with a carbon number of 3 to 8 is more preferably used. The (meth)acrylic acid alkyl ester having an alkyl group with a carbon number of 2 to 12 is preferably n-butyl (meth)acrylate in order to form, for example, a conductive pattern having an excellent characteristic of being formed of fine lines.

The content of (meth)acrylic acid alkyl ester having an alkyl group with a carbon number of 2 to 12, such as n-butyl (meth)acrylate, is preferably 10% by mass to 60% by mass of the total amount of vinyl monomers used for producing the vinyl resin (b1) in order to impart an excellent printing property and an excellent characteristic of being formed of fine lines without bleeding of ink. This is because, in this case, for example, a conductive pattern having an excellent characteristic of being formed of fine lines can be formed.

Examples of vinyl monomers other than the above-described vinyl monomers, which can be used for producing the vinyl resin (b1) include vinyl acetate, vinyl propionate, vinyl butylate, vinyl versatate, methyl vinyl ether, ethyl vinyl ether, propyl vinyl ether, butyl vinyl ether, amyl vinyl ether, hexyl vinyl ether, (meth)acrylonitrile, styrene, α-methylstyrene, vinyltoluene, vinylanisole, α-halostyrene, vinylnaphthalene, divinylstyrene, isoprene, chloroprene, butadiene, ethylene, tetrafluoroethylene, vinylidene fluoride, N-vinylpyrrolidone, polyethylene glycol mono(meth)acrylate, glycerol mono(meth)acrylate, vinyl sulfonate, styrene sulfonate, allyl sulfonate, 2-methylallyl sulfonate, 2-sulfoethyl (meth)acrylate, 2-sulfopropyl (meth)acrylate, (meth)acrylamide-t-butyl sulfonic acid, “ADEKA REASOAP PP-70 and PPE-710” (produced by ADEKA CORPORATION), and salts thereof; and vinyl monomers having another hydrophilic group such as a hydroxyl group, a sulfo group, a sulfate group, a phosphate group, or a phosphoric acid ester group.

The vinyl resin (b1) may be produced by polymerizing the above-described vinyl monomer by a conventional method. Specifically, the vinyl resin (b1) may be produced by a solution polymerization method in an organic solvent or an emulsion polymerization method and is preferably produced by the emulsion polymerization method.

Examples of the emulsion polymerization method include a method in which, for example, water, the vinyl monomer, a polymerization initiator, and as needed, a chain transfer agent, an emulsifying agent, and a dispersion stabilizer are charged into a reaction container by one operation and mixed to cause polymerization; a monomer dropping method in which the vinyl monomer is added dropwise into a reaction container to cause polymerization; and a pre-emulsion method in which the vinyl monomer, an emulsifying agent, and the like are mixed in water and the resulting mixture is added dropwise into a reaction container to cause polymerization.

The reaction temperature for the emulsion polymerization method varies depending on the type of vinyl monomer and polymerization initiator used but is preferably, for example, about 30° C. to 90° C. The reaction time for the emulsion polymerization method is preferably, for example, about 1 to 10 hours.

Examples of the polymerization initiator include persulfates such as potassium persulfate, sodium persulfate, and ammonium persulfate; organic peroxides such as benzoyl peroxide, cumene hydroperoxide, and t-butyl hydroperoxide; and hydrogen peroxide. These peroxides may be used alone for performing radical polymerization. Alternatively, polymerization can be performed using a redox polymerization initiator system including any of these peroxides and a reducing agent such as ascorbic acid, a metal salt of formaldehyde sulfoxylate, sodium thiosulfate, sodium bisulfite, or ferric chloride in combination. In addition, an azo initiator such as 4,4′-azobis(4-cyanovaleric acid) or 2,2′-azobis(2-amidinopropane)dihydrochloride may be used. These polymerization initiators may be used alone or in combination of two or more.

Examples of the emulsifying agent that can be used for producing the vinyl resin (b1) include an anionic surfactant, a nonionic surfactant, a cationic surfactant, and an amphoteric surfactant. In particular, an anionic surfactant is preferably used.

Examples of the anionic surfactant include higher alcohol sulfuric esters and salts thereof; alkylbenzene sulfonates, polyoxyethylene alkylphenyl sulfonates, polyoxyethylene alkyldiphenyl ether sulfonates, a sulfuric acid half ester salt of polyoxyethylene alkyl ether, alkyl diphenyl ether disulfonates, and succinic acid dialkyl ester sulfonate. Examples of the nonionic surfactant include polyoxyethylene alkyl ethers, polyoxyethylene alkylphenyl ethers, polyoxyethylene diphenyl ethers, a polyoxyethylene-polyoxypropylene block copolymer, and acetylenediol-based surfactants.

An example of the cationic surfactant is an alkylammonium salt or the like.

Examples of the amphoteric surfactant include alkyl(amide)betaine and an alkyldimethylamine oxide.

Examples of the emulsifying agent include, in addition to the above-described surfactants, fluorine-based surfactants, silicone-based surfactants, and emulsifying agents having an unsaturated polymerizable group in their molecules, which are generally called “reactive emulsifying agent”.

Examples of the reactive emulsifying agent include “LATEMUL S-180” (produced by Kao Corporation) and “Eleminol JS-2 and RS-30” (produced by Sanyo Chemical Industries, Ltd.) that include a sulfonic group and a salt thereof; “Aqualon HS-10, HS-20, and KH-1025” (produced by Dai-ichi Kogyo Seiyaku Co., Ltd.) and “ADEKA REASOAP SE-10 and SE-20” (produced by Asahi Denka Co., Ltd.) that include a sulfate group and a salt thereof; “New frontier A-229E” (produced by Dai-ichi Kogyo Seiyaku Co., Ltd.) that includes a phosphate group; and “Aqualon RN-10, RN-20, RN-30, and RN-50” (produced by Dai-ichi Kogyo Seiyaku Co., Ltd.) that includes a nonionic hydrophilic group.

The aqueous medium used for producing the vinyl resin (b1) may be only water or a mixed solution of water and a water-soluble solvent. Examples of the water-soluble solvent include polar solvents such as alcohols including methyl alcohol, ethyl alcohol, isopropyl alcohol, ethyl carbitol, ethylcellosolve, and butylcellosolve; and N-methylpyrrolidone.

An example of the chain transfer agent that can be used for producing the vinyl resin (b1) is lauryl mercaptan. The content of the chain transfer agent is preferably 0% by mass to 0.15% by mass and more preferably 0% by mass to 0.08% by mass of the total amount of the vinyl monomer used for producing the vinyl resin (b1).

The vinyl resin (b1) may also be produced through radical polymerization by the solution polymerization method.

A polymerization initiator may be used as needed in the solution polymerization method. Examples of the polymerization initiator include organic peroxides such as methyl ethyl ketone peroxide, benzoyl peroxide, dicumyl peroxide, t-butyl hydroperoxide, cumene hydroperoxide, lauroyl peroxide, t-butyl peroxyoctoate, t-butyl peroxybenzoate, lauroyl peroxide, and product name “NYPER BMT-K40” (produced by NOF CORPORATION, mixture of m-toluoyl peroxide and benzoyl peroxide); and azo compounds such as azobisisobutyronitrile and product name “ABN-E” [produced by JAPAN FINECHEM COMPANY, INC., 2,2′-azobis(2-methylbutyronitrile)].

Examples of the organic solvent that can be used in the solution polymerization method include alcohols such as methanol, ethanol, propanol, butanol, ethylene glycol methyl ether, and diethylene glycol methyl ether; ketones such as acetone, methyl ethyl ketone, methyl isobutyl ketone, and cyclohexanone; ethers such as tetrahydrofuran, dioxane, ethylene glycol dimethyl ether, and diethylene glycol dimethyl ether; hydrocarbons such as hexane, heptane, and octane; aromatics such as benzene, toluene, xylene, and cumene; ethyl acetate; and butyl acetate.

The content of the vinyl resin (b1) produced by the above-described method is preferably 5% by mass to 60% by mass and more preferably 10% by mass to 50% by mass of the total amount of resin composition for forming an absorbing layer used in the present invention.

The resin composition for forming an absorbing layer preferably includes a solvent such as an aqueous medium or an organic solvent in order to improve, for example, ease of coating on the surface of the substrate.

The aqueous medium may be, for example, only water or a mixed solution of water and a water-soluble solvent. Examples of the water-soluble solvent include polar solvents such as alcohols including methyl alcohol, ethyl alcohol, isopropyl alcohol, ethyl carbitol, ethylcellosolve, and butylcellosolve; and N-methylpyrrolidone.

When the aqueous medium is used, the content of the aqueous medium is preferably 30% by mass to 95% by mass and more preferably 40% by mass to 90% by mass of the total amount of resin composition for forming an absorbing layer used in the present invention.

Examples of the organic solvent that can be used as the solvent include toluene, ethyl acetate, and methyl ethyl ketone. When any of these organic solvents is used, the content of the organic solvent is preferably 30% by mass to 95% by mass and more preferably 40% by mass to 90% by mass of the total amount of resin composition for forming an absorbing layer used in the present invention.

In addition to the vinyl resin (b1) and the above-described solvent, as needed, the resin composition for forming an absorbing layer may include the crosslinking agent (b2) and publicly known additives such as a pH adjuster, a film-forming aid, a leveling agent, a bodying agent, a water repellent, and an antifoaming agent appropriately.

Examples of the crosslinking agent (b2) include a thermal crosslinking agent (b2-1) with which a reaction occurs at a relatively low temperature of about 25° C. or more and less than 100° C. to form a crosslinked structure, such as a metal chelate compound, a polyamine compound, an aziridine compound, a metal salt compound, or an isocyanate compound; a thermal crosslinking agent (b2-2) with which a reaction occurs at a relatively high temperature of about 100° C. or more to form a crosslinked structure, such as at least one compound selected from the group consisting of melamine compounds, epoxy compounds, oxazoline compounds, carbodiimide compounds, and blocked isocyanate compounds; and various types of photocrosslinking agents.

The resin composition for forming an absorbing layer including the thermal crosslinking agent (b2-1) is, for example, applied to the surface of the substrate and dried at a relatively low temperature. Subsequently, the conductive ink is applied (printed) to the dried resin composition. The temperature is then increased to a temperature of less than 100° C. to form a crosslinked structure. This allows formation of a conductive pattern having excellent durability such that the conductive pattern can maintain good conductivity without, for example, the absorbing layer (B) being dissolved and removed from the substrate even when, for example, a solvent such as a chemical agent for plating or a cleaning agent is adhered to the conductive pattern.

The resin composition for forming an absorbing layer including the thermal crosslinking agent (b2-2) is, for example, applied to the surface of the substrate and then dried at a low temperature, that is, a normal temperature (25° C.) or more and less than about 100° C. to produce an ink absorbing substrate in which no crosslinked structure is formed. Subsequently, the conductive ink or the like is applied to the ink absorbing substrate. Then, for example, the temperature is increased to 100° C. or more or preferably at about 120° C. to 300° C. to form a crosslinked structure. This allows formation of an excellent conductive pattern having excellent durability such that the conductive pattern can maintain good conductivity without, for example, the absorbing layer (B) being dissolved and removed from the substrate even when, for example, a solvent such as a chemical agent for plating or a cleaning agent is adhered to the conductive pattern.

Examples of the metal chelate compound that can be used as the thermal crosslinking agent (b2-1) include acetylacetone coordination compounds and acetoacetic ester coordination compounds of a polyvalent metal such as aluminium, iron, copper, zinc, tin, titanium, nickel, antimony, magnesium, vanadium, chromium, or zirconium. Acetylacetone aluminum, which is an acetylacetone coordination compound of aluminium, is preferably used.

Examples of the polyamine compound that can be used as the thermal crosslinking agent (b2-1) include tertiary amines such as triethylamine, triethylenediamine, and dimethylethanolamine.

Examples of the aziridine compound that can be used as the thermal crosslinking agent (b2-1) include 2,2-bishydroxymethylbutanol-tris[3-(1-aziridinyl)propionate], 1,6-hexamethylenediethyleneurea, and diphenylmethane-bis-4,4′-N,N′-diethyleneurea.

Examples of the metal salt compound that can be used as the crosslinking agent (b1-1) include aluminium-containing compounds such as aluminium sulfate, aluminium alum, aluminium sulfite, aluminium thiosulfate, polyaluminium chloride, aluminium nitrate nonahydrate, and aluminum chloride hexahydrate; and water-soluble metal salts such as titanium tetrachloride, tetraisopropyl titanate, titanium acetylacetonate, and titanium lactate.

Examples of the isocyanate compound that can be used as the thermal crosslinking agent (b2-1) include polyisocyanates such as tolylene diisocyanate, hydrogenated tolylene diisocyanate, triphenylmethane triisocyanate, methylenebis(4-phenylmethane)triisocyanate, isophorone diisocyanate, hexamethylene diisocyanate, and xylylene diisocyanate; an isocyanurate-type polyisocyanate compound produced using any one of these polyisocyanates; a trimethylolpropane adduct of any one of these polyisocyanates; and a polyisocyanate group-containing urethane produced by reacting any one of these polyisocyanate compounds with a polyol such as trimethylolpropane. In particular, a nurate of hexamethylene diisocyanate, an adduct of hexamethylene diisocyanate with trimethylolpropane or the like, an adduct of tolylene diisocyanate with trimethylolpropane or the like, and an adduct of xylylene diisocyanate with trimethylolpropane or the like are preferably used.

Examples of the melamine compound that can be used as the thermal crosslinking agent (b2-2) include hexamethoxymethylmelamine, hexaethoxymethylmelamine, hexapropoxymethylmelamine, hexabutoxymethylmelamine, hexapentyloxymethylmelamine, hexahexyloxymethylmelamine, and a mixed ether melamine of any two of these melamine compounds. In particular, trimethoxymethylmelamine and hexamethoxymethylmelamine are preferably used. Examples of these melamine compounds that are commercially available include BECKAMINE M-3, APM, and J-101 (produced by DIC Corporation).

When the melamine compound is used, a catalyst such as an organic amine salt may be used in order to promote the self-crosslinking reaction of the melamine compound. Examples of such a catalyst that is commercially available include Catalyst ACX and 376. The content of the catalyst is preferably about 0.01% by mass to 10% by mass of the total amount of the melamine compound.

Examples of the epoxy compound that can be used as the thermal crosslinking agent (b2-2) include polyglycidyl ethers of an aliphatic polyhydric alcohol, such as ethylene glycol diglycidyl ether, propylene glycol diglycidyl ether, hexamethylene glycol diglycidyl ether, cyclohexanediol diglycidyl ether, glycerin diglycidyl ether, glycerin triglycidyl ether, trimethylolpropane triglycidyl ether, and pentaerithritol tetraglycidyl ether; polyglycidyl ethers of a polyalkylene glycol, such as polyethylene glycol diglycidyl ether, polypropylene glycol diglycidyl ether, and polytetramethylene glycol diglycidyl ether; polyglycidylamines such as 1,3-bis(N,N′-diglycidylaminoethyl)cyclohexane; polyglycidyl esters of a polybasic carboxylic acid [e.g., oxalic acid, adipic acid, butanetricarboxylic acid, maleic acid, phthalic acid, terephthalic acid, isophthalic acid, or benzenetricarboxylic acid]; bis phenol A epoxy resins such as a condensation product of bis phenol A and epichlorohydrin and an ethylene oxide-adduct of the condensation product of bis phenol A and epichlorohydrin; phenol novolac resins; and various vinyl (co)polymers having an epoxy group in their side chain. In particular, polyglycidylamines such as 1,3-bis(N,N′-diglycidylaminoethyl)cyclohexane and polyglycidyl ethers of an aliphatic polyhydric alcohol, such as glycerin diglycidyl ether are preferably used.

Examples of the epoxy compound include, in addition to the above-described epoxy compounds, glycidyl group-containing silane compounds such as γ-glycidoxypropyltrimethoxysilane, γ-glycidoxypropyltriethoxysilane, γ-glycidoxypropylmethyldimethoxysilane, γ-glycidoxypropylmethyldiethoxysilane, β-(3,4-epoxycyclohexyl)ethyltrimethoxysilane, β-(3,4-epoxycyclohexyl)ethyltriethoxysilane, β-(3,4-epoxycyclohexyl)ethylmethyldiethoxysilane, and γ-glycidoxypropyltriisopropenyloxysilane.

Examples of the oxazoline compound that can be used as the thermal crosslinking agent (d1-2) include 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,4′-dimethyl-2-oxazoline), 2,2′-p-phenylene-bis-(2-oxazoline), 2,2′-m-phenylene-bis-(2-oxazoline), 2,2′-m-phenylene-bis-(4,4′-dimethyl-2-oxazoline), bis-(2-oxazolinylcyclohexane) sulfide, and bis-(2-oxazolinylnorbornan)sulfide.

The oxazoline compound may be, for example, a polymer including an oxazoline group which is produced by polymerizing the following addition-polymerizable oxazoline in combination with other monomers as needed.

Examples of the addition-polymerizable oxazoline include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-methyl-2-oxazoline, and 2-isopropenyl-5-ethyl-2-oxazoline. These addition-polymerizable oxazolines may be used alone or in combination of two or more. In particular, 2-isopropenyl-2-oxazoline, which is industrially easily available, is preferably used.

Examples of the carbodiimide compound that can be used as the thermal crosslinking agent (b2-2) include poly[phenylenebis(dimethylmethylene)carbodiimide] and poly(methyl-1,3-phenylenecarbodiimide). Examples of such carbodiimide compounds that are commercially available include CARBODILITE V-01, V-02, V-03, V-04, V-05, and V-06 (produced by Nisshinbo Chemical Inc.) and UCARLINK XL-29SE and XL-29 MP (produced by Union Carbide Corporation).

Examples of the blocked isocyanate compound that can be used as the thermal crosslinking agent (b2-2) include, among the above-described isocyanate compounds shown as examples of the thermal crosslinking agent (b2-1), isocyanate compounds in which some or all of their isocyanate groups are blocked using a blocking agent.

Examples of the blocking agent include phenol, cresol, 2-hydroxypyridine, butylcellosolve, propylene glycol monomethyl ether, benzyl alcohol, methanol, ethanol, n-butanol, isobutanol, dimethyl malonate, diethyl malonate, methyl acetoacetate, ethyl acetoacetate, acetylacetone, butyl mercaptan, dodecyl mercaptan, acetanilide, acetamide, ε-caprolactam, δ-valerolactam, γ-butyrolactam, succinimide, maleimide, imidazole, 2-methylimidazole, urea, thiourea, ethylene urea, formamidoxime, acetaldoxime, acetoxime, methyl ethyl ketoxime, methyl isobutyl ketoxime, cyclohexanone oxime, diphenylaniline, aniline, carbazole, ethyleneimine, and polyethyleneimine.

An example of the blocked isocyanate compound that is commercially available is water dispersion-type ERASTRON BN-69 (produced by Dai-ichi Kogyo Seiyaku Co., Ltd.) When the crosslinking agent (b2) is used, the vinyl resin (b1) preferably includes a functional group capable of reacting with a crosslinkable functional group of the crosslinking agent (b2). Specifically, vinyl resins including a hydroxyl group or a carboxyl group are preferably used as the vinyl resin (b1) together with the crosslinking agent (b2) that is a (blocked) isocyanate compound, a melamine compound, an oxazoline compound, or a carbodiimide compound.

The content of the crosslinking agent (b2) varies depending on the type of crosslinking agent and the like. However, generally, the content of the crosslinking agent (b2) is preferably 0.01% by mass to 60% by mass and more preferably 0.1% by mass to 50% by mass of the amount of vinyl resin (b1) in order to produce a conductive pattern having an excellent characteristic of being formed of fine lines.

In particular, when the crosslinking agent (b2) is a melamine compound, which is capable of causing a self-condensation reaction, the content of the crosslinking agent (b2) is preferably 0.1% by mass to 30% by mass, more preferably 0.1% by mass to 10% by mass, and further preferably 0.5% by mass to 5% by mass of the amount of vinyl resin (B2).

The crosslinking agent (b2) is preferably added to the resin composition for forming an absorbing layer prior to application of the resin composition for forming an absorbing layer to the surface of the substrate or impregnation of the substrate with the resin composition for forming an absorbing layer.

The resin composition for forming an absorbing layer used in the present invention may include, in addition to the above-described additives, solvent-soluble or solvent-dispersible thermosetting resins such as a phenol resin, a urea resin, a melamine resin, a polyester resin, a polyamide resin, and an urethane resin.

The resin layer (B1) is formed over a portion or the entirety of the surface of the substrate using the resin composition for forming an absorbing layer by, for example, a method in which the resin composition for forming an absorbing layer is applied to a portion or the entirety of one or both surfaces of the substrate or the substrate is impregnated with the resin composition for forming an absorbing layer; and subsequently a solvent such as an aqueous medium or a solvent, which may be included in the resin composition for forming an absorbing layer, is removed.

The resin composition for forming an absorbing layer is applied to a portion or the entirety of the surface of the substrate or the substrate is impregnated with the resin composition for forming an absorbing layer by a publicly known method, and examples thereof include a gravure method, a coating method, a screen method, a roller method, a rotary method, a spray method, and an inkjet method.

After the resin composition for forming an absorbing layer is, for example, applied to the substrate, the solvent such as an aqueous medium or a solvent, which may be included in the resin composition for forming an absorbing layer, is removed generally by, for example, being dried with a dryer. The temperature at which the coated item is dried is such that no deformation or the like of the substrate is caused at the temperature. However, when the resin composition for forming an absorbing layer is thermally crosslinkable, it is important to perform heating in the drying step at a temperature at which a crosslinking reaction of the resin layer (B1) does not proceed and no crosslinked structure is formed. Specifically, the drying temperature is preferably about 25° C. or more and less than 100° C.

The amount of resin composition for forming an absorbing layer adhered to the substrate is preferably 0.1 g/m² to 50 g/m² in order to maintain a good production efficiency and more preferably 0.5 g/m² to 40 g/m² in consideration of ink absorbency and production cost in terms of solid content per area of the substrate.

An increase in the amount of resin composition for forming an absorbing layer adhered to the substrate further improves the color development property of the printed item. However, an increase in the amount of the adhered resin composition for forming an absorbing layer may cause the feel of the printed item to be a little hard. Thus, when a good flexibility is required as in an organic EL capable of being bent, the amount of the adhered resin composition for forming an absorbing layer is preferably relatively small, that is, about 0.5 g/m² to 30 g/m². Depending on the application or the like, the amount of the adhered resin composition for forming an absorbing layer may be about more than 30 g/m² and 100 g/m² or less. That is, a relatively thick film may be formed.

Next, Step (2) will be described.

In Step (2), the conductive ink is applied (printed) to the conductive-ink absorbing substrate produced in Step (1).

Examples of the conductive ink that can be used for application include conductive inks containing a conductive substance (c), a solvent, and as needed, additives such as a dispersing agent.

The conductive substance (c) may be a transition metal or a compound of a transition metal. In particular, ionic transition-metals such as copper, silver, gold, nickel, palladium, platinum, and cobalt are preferably used. Silver, gold, copper, and the like are more preferably used in order to form a conductive pattern having a low electric resistance and a high corrosion resistance.

The conductive substance (c) is preferably in the form of particles having an average particle diameter of about 1 to 50 nm. The term “average particle diameter” herein refers to a median diameter (D50) determined with a laser diffraction/scattering particle size distribution analyzer.

The content of the conductive substance (c) that is the above-described metal or the like is preferably 5% by mass to 60% by mass and more preferably 10% by mass to 50% by mass of the total amount of conductive ink.

Various types of organic solvents and aqueous mediums such as water may be used as the solvent used in the conductive ink.

In the present invention, solvent-based conductive ink containing an organic solvent as a main solvent of the conductive ink, water-based conductive ink containing water as the main solvent, or conductive ink containing both an organic solvent and water may be used appropriately.

Generally, in many cases, the conductive ink is applied in the form of fine lines because the conductive ink is used for forming a pattern of an electric circuit or the like. Thus, the amount of solvent brought into a contact with the surface of the resin layer (B1) to which the conductive ink is applied is relatively small compared with the case where a photo or the like is printed using an ordinary pigment ink or the like. Therefore, even when either an aqueous medium or an organic solvent is used as the solvent contained in the conductive ink, the resin layer (B1) can absorb the solvent and thereby allows the conductive substance (c) contained in the conductive ink to be fixed.

In particular, the conductive ink containing water as the main solvent of the conductive ink, the conductive ink containing both an organic solvent and water, and the solvent-based conductive ink containing an organic solvent as a main solvent of the conductive ink are preferably used in order to improve the characteristic of being formed of fine lines, adhesion, and the like of, for example, the conductive pattern to be formed. The solvent-based conductive ink containing an organic solvent as a main solvent of the conductive ink is more preferably used.

Examples of the solvent used for the solvent-based conductive ink include alcohol solvents such as methanol, ethanol, n-propanol, isopropyl alcohol, n-butanol, isobutyl alcohol, sec-butanol, tert-butanol, heptanol, hexanol, octanol, nonanol, decanol, undecanol, dodecanol, tridecanol, tetradecanol, pentadecanol, stearyl alcohol, ceryl alcohol, cyclohexanol, terpineol, terpineol, and dihydroterpineol; glycol solvents such as 2-ethyl-1,3-hexanediol, ethylene glycol, diethylene glycol, triethylene glycol, polyethylene glycol, propylene glycol, dipropylene glycol, 1,3-butanediol, 1,4-butanediol, and 2,3-butanediol; glycol ether solvents such as ethylene glycol monomethyl ether, ethylene glycol monoethyl ether, ethylene glycol monobutyl ether, diethylene glycol monoethyl ether, diethylene glycol monomethyl ether, diethylene glycol monobutyl ether, ethylene glycol monoethyl ether acetate, ethylene glycol monomethyl ether acetate, ethylene glycol monobutyl ether acetate, diethylene glycol monoethyl ether acetate, diethylene glycol monobutyl ether acetate, diethylene glycol diethyl ether, diethylene glycol dimethyl ether, diethylene glycol dibutyl ether, tetraethylene glycol dimethyl ether, tetraethylene glycol monobutyl ether, propylene glycol monomethyl ether, dipropylene glycol monomethyl ether, tripropylene glycol monomethyl ether, propylene glycol monopropyl ether, dipropylene glycol monopropyl ether, propylene glycol monobutyl ether, dipropylene glycol monobutyl ether, tripropylene glycol monobutyl ether, propylene glycol monomethyl ether acetate, dipropylene glycol monomethyl ether acetate, propylene glycol diacetate, propylene glycol phenyl ether, and dipropylene glycol dimethyl ether; and polar solvents such as glycerin.

Among the polar solvents, the conductive ink containing the glycol solvent is preferably selected in consideration of its compatibility with the resin layer (B1) in order to prevent the glycol solvent from causing bleeding, a reduction in adhesion, and the like and thereby realize the characteristic of being formed of fine lines such that an increase in the density of electronic circuits can be realized.

Among these glycol solvents, in particular, ethylene glycol, diethylene glycol, triethylene glycol, 1,3-butanediol, 1,4-butanediol, and 2,3-butanediol are more preferably used.

The solvent-based conductive ink may be used in combination with a ketone solvent such as acetone, cyclohexanone, or methyl ethyl ketone in order to control the properties of the solvent-based conductive ink. The solvent-based conductive ink may also be used, as needed, in combination with an ester solvent such as ethyl acetate, butyl acetate, 3-methoxybutyl acetate, or 3-methoxy-3-methyl-butyl acetate; a hydrocarbon solvent such as toluene and particularly hydrocarbon solvents having a carbon number of 8 or more; a nonpolar solvent such as octane, nonane, decane, dodecane, tridecane, tetradecane, cyclooctane, xylene, mesitylene, ethylbenzene, dodecylbenzene, tetralin, or trimethylbenzene-cyclohexane. The solvent-based conductive ink may further be used in combination with a mixed solvent such as mineral spirit and solvent naphtha.

The aqueous medium used as the solvent of the conductive ink may be, for example, water only or a mixed solution of water and a water-soluble solvent. Examples of the water-soluble solvent include polar solvents such as alcohols including methyl alcohol, ethyl alcohol, isopropyl alcohol, ethyl carbitol, ethyl cellosolve, and butyl cellosolve; and N-methylpyrrolidone.

The content of the solvent contained in the conductive ink is more preferably 35% by mass to 90% by mass of the total amount of conductive ink. The content of the polar solvent is preferably 10% by mass to 100% by mass of the total amount of solvent.

In addition to the above-described metals and solvents, the conductive ink may include various types of additives as needed.

A dispersing agent may be used as the additive in order to, for example, improve dispersibility of the metal in the solvent.

Examples of the dispersing agent include high-molecular amine dispersing agents such as polyethyleneimine and polyvinylpyrrolidone; high-molecular hydrocarbon dispersing agents having a carboxyl group in their molecules, such as polyacrylic acid and carboxymethylcellulose; and high-molecular dispersing agents having a polar group, such as polyvinyl alcohol, a styrene-maleic acid copolymer, an olefin-maleic acid copolymer, and copolymers having a polyethyleneimine portion and a polyethylene oxide portion in one molecule. Polyvinyl alcohol may be used as the dispersing agent even when the solvent-based conductive ink is used.

The conductive ink may be applied (printed) to the above-described conductive-ink absorbing substrate or the like by, for example, an inkjet printing method, a screen printing method, a relief reverse printing method, a gravure offset printing method, an offset printing method, a spin coating method, a spray coating method, a bar coating method, a die coating method, a slit coating method, a roll coating method, or a dip coating method.

In particular, an inkjet printing method, a screen printing method, a relief reverse printing method, or a gravure offset printing method is preferably employed in order to print fine lines having a width of about 0.01 μm to 100 μm, which is required for realizing an increase in the density of electronic circuits or the like. More preferably, an inkjet printing method is employed.

In the inkjet printing method, an item generally referred to as “inkjet printer” may be used. Specific examples of the inkjet printer include Konica Minolta EB100 and XY100 (produced by Konica Minolta IJ Technologies, Inc.), Dimatix Materials Printer DMP-3000, and Dimatix Materials Printer DMP-2831 (produced by Fujifilm Corporation).

The screen printing method is a method in which the conductive ink is applied to the surface of the resin layer (B1), which is to be formed into the absorbing layer (B), using a mesh-like screen plate. Specifically, a conductive pattern having a predetermined pattern shape is printed using a screen plate composed of a metal, which is generally referred to as “metal mesh”, to form a conductive pattern having a predetermined pattern shape.

The relief reverse printing method is a method in which the conductive ink is applied to a blanket to form a conductive ink-coated surface and the deposited conductive ink is then transferred to the resin layer (B1).

The blanket is preferably a silicone blanket composed of silicone.

The conductive ink is applied to the blanket to form a layer composed of the conductive ink. A relief printing plate including a plate corresponding to the predetermined pattern as needed is pressed against the layer composed of the conductive ink. Thus, the conductive ink on the blanket, which is brought into a contact with the relief printing plate, is transferred to the surface of the relief printing plate.

Subsequently, the blanket is brought into a contact with the resin layer (B1), and thereby the conductive ink remaining on the blanket is transferred to the surface of the resin layer (B1). Thus, the conductive pattern having a predetermined pattern can be formed.

An example of the gravure offset printing method is a method in which the conductive ink is supplied into groove portions in an intaglio printing plate having a predetermined pattern shape, a blanket is pressed against the surface of the intaglio printing plate to transfer the conductive ink to the blanket, and subsequently the conductive ink on the blanket is transferred to the resin layer (B1).

Examples of the intaglio printing plate include a gravure plate and a glass intaglio plate formed by etching a glass plate.

The blanket may be a blanket having a multilayered structure including a silicone rubber layer, a polyethylene terephthalate layer, a sponge-like layer, and the like. A blanket wound around a rigid cylinder, which is referred to as “blanket cylinder”, is generally used.

The conductive pattern according to the present invention is preferably produced through a firing step in order to form the conductive layer (C) having conductivity by applying (printing) the conductive ink to the surface of the conductive-ink absorbing substrate produced in Step (1) and subsequently adhering and joining the conductive substance (c) contained in the conductive ink to the conductive-ink absorbing layer.

Firing is preferably performed at about 80° C. to 300° C. for about 2 to 200 minutes. Firing may be performed in the atmosphere. In order to prevent the metal from oxidizing, a part or the entirety of the firing step may be conducted in a reducing atmosphere.

The firing step may be conducted using, for example, an oven, a hot-air drying oven, an infrared drying oven, laser irradiation, or the like.

When a crosslinked structure is formed in the resin layer (B1) by heating the printed item after application of the conductive ink, heating may be performed in order to form the crosslinked structure in Step (3) described below immediately after the application of the conductive ink. This heating step also serves as the firing step. Thus, both the formation of the crosslinked structure and imparting of conductivity can be performed at the same time.

When a crosslinked structure is formed in the resin layer (B1) by irradiating the surface of the printed item with light to form the absorbing layer (B) after application of the conductive ink, it is preferable to impart conductivity through the firing step and subsequently form a crosslinked structure in the resin layer (B1) in Step (3).

Then, Step (3) will be described.

In Step (3), the coated item prepared in Step (2) is, for example, heated or irradiated with light to form a crosslinked structure in the resin layer (B1) to which the conductive substance (c) is adhered.

The crosslinked structure may be formed by, for example, a crosslinking reaction between a crosslinkable functional group of the vinyl resin (b1) and the crosslinking agent (b2), a crosslinking reaction between crosslinkable functional groups of the vinyl resin (b1), or a self-crosslinking reaction of the crosslinking agent (b2).

The crosslinking reaction can be proceeded by, for example, being heated. In particular, a method in which heating is performed to cause a crosslinking reaction is preferably employed in order to improve the efficiency of producing a conductive pattern because such a method also serves as the firing step.

The heating temperature is preferably about 80° C. to 300° C., more preferably 100° C. to 300° C., and further preferably 120° C. to 300° C., which varies depending on the type of the crosslinking agent (b2) used, the combination of crosslinkable functional groups, or the like. When the substrate is relatively heat-sensitive, the upper limit of the heating temperature is preferably 200° C. or less and more preferably 150° C. or less. In Step (3), for example, an oven, a hot-air drying oven, and an infrared drying oven may be used.

A conductive pattern produced by the above-described method, in which a crosslinked structure is formed in the resin layer (B1) after the conductive ink is applied to the absorbing layer (B), has durability such that the conductive pattern can maintain good conductivity without, for example, the absorbing layer (B) being dissolved and removed from the substrate even when, for example, a solvent such as a chemical agent for plating or a cleaning agent is adhered to the conductive pattern.

This conductive pattern also has an excellent printing property even when the conductive ink containing the conductive substance (c) is used. Thus, this conductive pattern realizes printing of fine lines having a width of about 0.01 μm to 200 μm and preferably about 0.01 μm to 150 μm, which is required for forming a conductive pattern of an electronic circuit or the like, without bleeding (characteristic of being formed of fine lines). Therefore, this conductive pattern is suitably used in the field of printed electronics, such as formation of a substrate used for forming circuits including an electronic circuit and an integrated circuit using silver ink; formation of layers constituting an organic solar cell, an electronic book reader, an organic EL, an organic transistor, a flexible printed substrate, RFID, or the like and their peripheral wires; wiring in electromagnetic shielding of plasma display; and the like.

### EXAMPLES

Hereafter, the present invention will be described in detail with Examples.

### Example 1

### Preparation of Resin Composition for Forming Absorbing Layer (I-1) and Preparation of Conductive-Ink Absorbing Substrates (II-1) Using the Same

Into a reaction container equipped with a stirrer, a reflux cooling tube, a nitrogen-introduction tube, a thermometer, and a dropping funnel, 115 parts by mass of deionized water and 4 parts by mass of LATEMUL E-118B (produced by Kao Corporation, active ingredient: 25% by mass) were charged. The mixture was heated to 75° C. under a nitrogen flow.

A vinyl monomer mixture of 51 parts by mass of methyl methacrylate, 15 parts by mass of N-n-butoxymethylacrylamide, 31 parts by mass of n-butyl acrylate, 2 parts by mass of acrylamide, and 1 part by mass of methacrylic acid and a portion (5 parts by mass) of a monomer pre-emulsion prepared by mixing 4 parts by mass of Aqualon KH-1025 (produced by Dai-ichi Kogyo Seiyaku Co., Ltd., active ingredient: 25% by mass) and 15 parts by mass of deionized water were added in the reaction container under stirring. Subsequently, 0.1 parts by mass of potassium persulfate was added in the reaction container. The resulting mixture was polymerized for 60 minutes while keeping the temperature inside the reaction container at 75° C.

While keeping the temperature inside the reaction container at 75° C., the remaining monomer pre-emulsion (114 parts by mass) and 30 parts by mass of an aqueous potassium persulfate solution (active ingredient: 1.0% by mass) were each added dropwise using different dropping funnels over 180 minutes. After the completion of dropping, the resulting mixture was stirred for 60 minutes at the same temperature.

The temperature inside the reaction container was reduced to 40° C., and ammonia water (active ingredient: 10% by mass) was used so that the pH of a water dispersion in the reaction container reached 8.5.

Subsequently, deionized water was used so that the nonvolatile content of the mixture reached 40% by mass. The resulting mixture was filtered through a 200-mesh filter cloth to prepare a resin composition for forming an absorbing layer (I-1) used in the present invention.

This resin composition for forming an absorbing layer (I-1) was applied to the surfaces of three types of substrates described in (i) to (iii) below using a bar coater so that the dried film thickness was 3 μm and dried at 70° C. for 3 minutes using a hot-air drying oven. Thus, three types of conductive-ink absorbing substrates (II-1) including a conductive-ink absorbing layer formed on the respective substrates were prepared.

### [Substrate]

(i) PET: polyethylene terephthalate film (COSMOSHINE A4300 produced by TOYOBO CO., LTD., thickness: 50 μm)

(ii) PI: polyimide film (Kapton 200H produced by DU PONT-TORAY CO., LTD., thickness: 50 μm)

(iii) GL: glass: glass plate, JIS 83202, thickness: 2 mm

### Examples 2 to 4

### Preparation of Resin Compositions for Forming Absorbing Layer (I-2) to (I-4) and Preparation of Conductive-Ink Absorbing Substrates (II-2) to (II-4) Using the Same

Resin compositions for forming an absorbing layer (I-2) to (I-4) having a nonvolatile content of 40% by mass were prepared as in Example 1, except that the composition of the vinyl monomer mixture was changed to the composition shown in Table 1 below.

Conductive-ink absorbing substrates (II-2) to (II-4) were prepared as in Example 1, except that the resin compositions for forming an absorbing layer (I-2) to (I-4) were used respectively instead of the resin composition for forming an absorbing layer (I-1).

### Example 5

### Preparation of Resin Composition for Forming Absorbing Layer (I-5) and Preparation of Conductive-Ink Absorbing Substrates (II-5) Using the Same

Into a reaction container equipped with a stirrer, a reflux cooling tube, a nitrogen-introduction tube, a thermometer, and a dropping funnel, 115 parts by mass of deionized water and 4 parts by mass of LATEMUL E-118B (produced by Kao Corporation, active ingredient: 25% by mass) were charged. The mixture was heated to 75° C. under a nitrogen flow.

A vinyl monomer mixture of 57 parts by mass of methyl methacrylate, 35 parts by mass of butyl acrylate, 2 parts by mass of acrylamide, 1 part by mass of methacrylic acid, and 5 parts by mass of 4-hydroxybutyl acrylate and a portion (5 parts by mass) of a monomer pre-emulsion prepared by mixing 4 parts by mass of Aqualon KH-1025 (produced by Dai-ichi Kogyo Seiyaku Co., Ltd., active ingredient: 25% by mass) and 15 parts by mass of deionized water were added in the reaction container under stirring. Subsequently, 0.1 parts by mass of potassium persulfate was added in the reaction container. The resulting mixture was polymerized for 60 minutes while keeping the temperature inside the reaction container at 75° C.

While keeping the temperature inside the reaction container at 75° C., the remaining monomer pre-emulsion (114 parts by mass) and 30 parts by mass of an aqueous potassium persulfate solution (active ingredient: 1.0% by mass) were each added dropwise using different dropping funnels over 180 minutes. After the completion of dropping, the resulting mixture was stirred for 60 minutes at the same temperature.

The temperature inside the reaction container was reduced to 40° C., and ammonia water (active ingredient: 10% by mass) was used so that the pH of a water dispersion in the reaction container reached 8.5.

Subsequently, deionized water was used so that the nonvolatile content of the mixture reached 40% by mass. The resulting mixture was filtered through a 200-mesh filter cloth to prepare a mixture including a vinyl polymer and water (nonvolatile content: 40% by mass).

A resin composition for forming an absorbing layer (I-5) having a nonvolatile content of 40% by mass was prepared by mixing 200 parts by mass of this mixture, 5 parts by mass of ERASTRON BN-69 (produced by Dai-ichi Kogyo Seiyaku Co., Ltd., isocyanate compound, active ingredient: 40% by mass), and deionized water.

Three types of conductive-ink absorbing substrates (II-5) including different substrates were prepared as in Example 1, except that the resin composition for forming an absorbing layer (I-5) was used instead of the resin composition for forming an absorbing layer (I-1).

### Example 6

### Preparation of Resin Composition for Forming Absorbing Layer (I-6) and Preparation of Conductive-Ink Absorbing Substrates (II-6) Using the Same

Into a reaction container equipped with a stirrer, a reflux cooling tube, a nitrogen-introduction tube, a thermometer, and a dropping funnel, 115 parts by mass of deionized water and 4 parts by mass of LATEMUL E-118B (produced by Kao Corporation, active ingredient: 25% by mass) were charged. The mixture was heated to 75° C. under a nitrogen flow.

A vinyl monomer mixture of 60 parts by mass of methyl methacrylate, 37 parts by mass of n-butyl acrylate, 2.0 parts by mass of acrylamide, and 1 part by mass of methacrylic acid and a portion (5 parts by mass) of a monomer pre-emulsion prepared by mixing 4 parts by mass of Aqualon KH-1025 (produced by Dai-ichi Kogyo Seiyaku Co., Ltd., active ingredient: 25% by mass) and 15 parts by mass of deionized water were added in the reaction container under stirring. Subsequently, 0.1 parts by mass of potassium persulfate was added in the reaction container. The resulting mixture was polymerized for 60 minutes while keeping the temperature inside the reaction container at 75° C.

While keeping the temperature inside the reaction container at 75° C., the remaining monomer pre-emulsion (114 parts by mass) and 30 parts by mass of an aqueous potassium persulfate solution (active ingredient: 1.0% by mass) were each added dropwise using different dropping funnels over 180 minutes. After the completion of dropping, the resulting mixture was stirred for 60 minutes at the same temperature.

The temperature inside the reaction container was reduced to 40° C., and ammonia water (active ingredient: 10% by mass) was used so that the pH of a water dispersion in the reaction container reached 8.5.

Subsequently, deionized water was used so that the nonvolatile content of the mixture reached 40% by mass. The resulting mixture was filtered through a 200-mesh filter cloth to prepare a mixture including a vinyl polymer and water (nonvolatile content: 40% by mass).

A resin composition for forming an absorbing layer (I-6) having a nonvolatile content of 40% by mass was prepared by mixing 200 parts by mass of this mixture, 3 parts by mass of a melamine compound [BECKAMINE M-3 (produced by DIC Corporation)], and deionized water.

Three types of conductive-ink absorbing substrates (II-6) including different substrates were prepared as in Example 1, except that the resin composition for forming an absorbing layer (I-6) was used instead of the resin composition for forming an absorbing layer (I-1).

### Examples 7 and 8

### Preparation of Resin Compositions for Forming Absorbing Layer (I-7) and (I-8) and Preparation of Conductive-Ink Absorbing Substrates (II-7) and (II-8) Using the Same

Resin compositions for forming an absorbing layer (I-7) and (I-8) having a nonvolatile content of 40% by mass were prepared as in Example 1, except that the composition of the vinyl monomer mixture was changed to the composition shown in Table 2 below.

Conductive-ink absorbing substrates (II-7) and (II-8) were prepared as in Example 1, except that the resin compositions for forming an absorbing layer (I-7) and (I-8) were used respectively instead of the resin composition for forming an absorbing layer (I-1).

### Example 9

### Preparation of Resin Composition for Forming Absorbing Layer (I-9) and Preparation of Conductive-Ink Absorbing Substrates (II-9) Using the Same

Into a reaction container equipped with a stirrer, a reflux cooling tube, a nitrogen-introduction tube, and a thermometer, a vinyl monomer mixture of 51 parts by mass of methyl methacrylate, 17 parts by mass of N-n-butoxymethylacrylamide, 31 parts by mass of n-butyl acrylate, and 1 part by mass of methacrylic acid and ethyl acetate were charged. The mixture was heated to 50° C. in a nitrogen atmosphere. Then, 2 parts by mass of 2,2′-azobis(2-methylbutyronitrile) was charged into the reaction container. The mixture was caused to react for 24 hours while keeping the temperature inside the reaction container at 50° C.

Subsequently, ethyl acetate was used so that the nonvolatile content of the mixture reached 20% by mass, and then the temperature inside the reaction container was reduced to 40° C. Thus, resin composition for forming an absorbing layer (I-9) was prepared, which included a vinyl resin and ethyl acetate and had a weight-average molecular weight of 400,000. The weight-average molecular weight was determined by gel permeation chromatography (GPC) using a high-performance liquid chromatograph HLC-8220 produced by TOSOH CORPORATION, TSKgelGMH XL×4 columns as columns, tetrahydrofuran as an eluent, and an R1 detector.

Conductive-ink absorbing substrates (II-9) were prepared as in Example 1, except that the resin composition for forming an absorbing layer (I-9) was used instead of the resin composition for forming an absorbing layer (I-1).

### Comparative Examples 1 to 3

### Preparation of Resin Compositions for Forming Absorbing Layer (I′-1) to (I′-3) for Comparison and Preparation of Conductive-Ink Absorbing Substrates (II′-1) to (II′-3) Using the Same

Resin compositions for forming an absorbing layer (I′-1) to (I′-3) for comparison having a nonvolatile content of 40% by mass were prepared as in Example 1, except that the composition of the vinyl monomer mixture was changed to the composition shown in Table 2 below.

Conductive-ink absorbing substrates (II′-1) to (II′-3) were prepared as in Example 1, except that the resin compositions for forming an absorbing layer (I′-1) to (I′-3) for comparison were used respectively instead of the resin composition for forming an absorbing layer (I-1).

TABLE 1

| | | Example | | | | | |
|---|---|---|---|---|---|---|---|
| | | 1 | 2 | 3 | 4 | 5 | 6 |
| MMA | Part by | 51.0 | 52.0 | 32.0 | 51.0 | 53.0 | 49.0 |
| NBMAM | mass | 15.0 | 5.0 | 45.0 | — | — | — |
| NIBMAM | | — | — | — | 15.0 | — | — |
| BA | | 31.0 | 35.0 | 20.0 | 31.0 | 35.0 | 37.0 |
| AM | | 2.0 | 2.0 | 2.0 | 2.0 | — | — |
| MAA | | 1.0 | 1.0 | 1.0 | 1.0 | 1.0 | 1.0 |
| HEMA | | — | 5.0 | — | — | 1.0 | 10.0 |
| CHMA | | — | — | — | — | — | — |
| 4HBA | | — | — | — | — | 5.0 | — |
| Crosslinking | | — | — | — | — | 5.0 | — |
| agent 1 | | | | | | | |
| Crosslinking | | — | — | — | — | — | 3.0 |
| agent 2 | | | | | | | |

| | | | | | | |
|---|---|---|---|---|---|---|
| Components | NBMAM | NBMAM/ | NBMAM | NIBMAM | 4HBA/HEMA/ | HEMA/ |
| forming crosslinked | | HEMA | | | Crosslinking | Crosslinking |
| structure | | | | | agent 1 | agent 2 |

TABLE 2

| | | Example | | | Comparative example | | |
|---|---|---|---|---|---|---|---|
| | | 7 | 8 | 9 | 1 | 2 | 3 |
| MMA | Part by | 50.0 | 20.0 | 50.0 | 5.0 | 80.0 | 60.0 |
| NBMAM | mass | 15.0 | 15.0 | 17.0 | 15.0 | 15.0 | — |
| NIBMAM | | — | — | — | — | — | — |
| BA | | 34.0 | 42.0 | 27.0 | 77.0 | 4.0 | 37.0 |
| AM | | — | 2.0 | — | 2.0 | — | 2.0 |
| MAA | | 1.0 | 1.0 | 1.0 | 1.0 | 1.0 | 1.0 |
| HEMA | | — | | 5.0 | — | — | — |
| CHMA | | — | 20.0 | — | — | — | — |
| 4HBA | | — | — | — | — | — | — |
| Crosslinking | | — | — | — | — | — | — |
| agent 1 | | | | | | | |
| Crosslinking | | — | — | — | — | — | — |
| agent 2 | | | | | | | |

| | | | | | | |
|---|---|---|---|---|---|---|
| Components forming | NBMAM | NBMAM | NBMAM/ | NBMAM | NBMAM | None |
| crosslinked structure | | | HEMA | | | |

### Explanation of Abbreviations Used in Tables 1 to 3

MMA: methyl methacrylate

NBMAM: N-n-butoxymethylacrylamide

NIBMAM: N-isobutoxymethylacrylamide

BA: n-butyl acrylate

MAA: methacrylic acid

AM: acrylamide

HEMA: 2-hydroxyethyl methacrylate

CHMA: cyclohexyl methacrylate

4HBA: 4-hydroxybutyl acrylate

Crosslinking agent 1: blocked isocyanate compound [ERASTRON BN-69(produced by Dai-ichi Kogyo Seiyaku Co., Ltd.)]

Crosslinking agent 2: melamine compound [BECKAMINE M-3 (produced by DIC Corporation), trimethoxymethylmelamine]

### [Method for Preparing Ink]

### [Preparation of Nano-Silver Ink 1 for Inkjet Printing]

Silver particles having an average particle diameter of 30 nm were dispersed in a mixed solvent of 65 parts by mass of diethylene glycol diethyl ether, 18 parts by mass of γ-butyrolactone, 15 parts by mass of tetraethylene glycol dimethyl ether, and 2 parts by mass of tetraethylene glycol monobutyl ether to prepare solvent-based nano-silver ink 1 for inkjet printing.

### [Preparation of Nano-Silver Ink 2 for Inkjet Printing]

Silver particles having an average particle diameter of 30 nm were dispersed in a mixed solvent of 45 parts by mass of ethylene glycol and 55 parts by mass of ion-exchange water to prepare water-based nano-silver ink 2 for inkjet printing.

### [Preparation of Nano-Silver Ink 3 for Inkjet Printing]

Silver particles having an average particle diameter of 30 nm were dispersed in a solvent that was tetradodecane to prepare solvent-based nano-silver ink 3 for inkjet printing.

### [Preparation of Silver Paste for Screen Printing]

A silver paste (NPS, produced by Harima Chemicals Group, Inc.) was used.

### [Preparation of Silver Ink for Relief Reverse Printing]

Ink for relief reverse printing was prepared by mixing 48% by mass of Fine Sphere SVE102 (produced by Nippon Paint Co., Ltd., solid content: about 30% by mass) as conductive particles, 50% by mass of methanol as a viscosity modifier, and 2% by mass of TF-1303 (produced by DIC Corporation, solid content: about 30% by mass) as a surface energy modifier.

### [Preparation of Silver Ink for Gravure Offset Printing]

Silver ink for gravure offset printing was prepared by mixing 85% by mass of Silvest AGS-050 (produced by Tokuriki Chemical Research Co., Ltd.) as conductive particles, and 5% by mass of VYLON 200 (produced by TOYOBO CO., LTD.) and 10% by mass of diethylene glycol monoethyl ether acetate as binder resins.

### [Printing by Inkjet Printing Method]

Using each of the nano-silver inks 1 to 3 for inkjet printing, a straight line with a length of about 1 cm, a line width of 100 μm and a film thickness of 0.5 μm was printed on the surfaces of the three types of conductive-ink absorbing substrates prepared using the substrates (i), (ii), and (iii) with an inkjet printer (inkjet test machine: EB100, evaluation printer head: KM512L, ejection rate: 42 pl, produced by Konica Minolta IJ Technologies, Inc.). Then, drying was performed at 150° C. for 30 minutes to prepare printed items (conductive patterns). In the conductive-ink absorbing substrates of Examples 1 to 9 and Comparative examples 1 to 3, a crosslinked structure was formed in the absorbing layer through the step of drying at 150° C. for 30 minutes subsequent to printing using the above-described ink. Whether a crosslinked structure was formed or not was assessed on the basis of “gel fraction in an absorbing layer formed by being dried at a normal temperature (23° C.) and subsequently being heated at 70° C.” and “gel fraction in an absorbing layer formed by being heated at 150° C.” shown in Tables 3 and 4. Specifically, a crosslinked structure was considered to be formed by being heated at a high temperature when the gel fraction in an absorbing layer prepared by being heated at 150° C. was higher than the gel fraction (uncrosslinked state) in an absorbing layer prepared by being dried at a normal temperature and subsequently being heated at 70° C. by 25% by mass or more.

The gel fraction in a conductive-ink absorbing layer formed by being dried at a normal temperature (23° C.) and subsequently being heated at 70° C. was determined by the following method.

A resin composition for forming an absorbing layer was poured onto a polypropylene film enclosed by thick paper so that the dried film thickness was 100 dried at 23° C. and a humidity of 65% for 24 hours, and then heated at 70° C. for 3 minutes to prepare an absorbing layer. This absorbing layer was removed from the polypropylene film, and a 3-cm-long and 3-cm-wide piece was cut from this absorbing layer to prepare a test piece. The mass (X) of the test piece 1 was measured, and the test piece 1 was immersed in 50 ml of methyl ethyl ketone kept at 25° C. for 24 hours.

A residue (insoluble content) of the test piece 1 that was not dissolved in methyl ethyl ketone by immersion was filtered through a 300-mesh metal screen.

The residue was dried at 108° C. for 1 hour, and the mass (Y) of the dried residue was measured.

Then, the gel fraction was determined on the basis of the expression [(Y)/(X)]×100 using the measured mass (X) and mass (Y).

The “gel fraction in an absorbing layer formed by being heated at 150° C.” was determined by the following method.

A resin composition for forming an absorbing layer was poured into a polypropylene film enclosed by thick paper so that the dried film thickness was 100 μm, dried at 23° C. and a humidity of 65% for 24 hours, and then heated and dried at 150° C. for 30 minutes to prepare an absorbing layer. This absorbing layer was removed from the polypropylene film, and a 3-cm-long and 3-cm-wide piece was cut from this absorbing layer to prepare a test piece 2. The mass (X′) of the test piece 2 was measured, and the test piece 2 was immersed in 50 ml of methyl ethyl ketone kept at 25° C. for 24 hours.

A residue (insoluble content) of the test piece 2 that was not dissolved in methyl ethyl ketone by immersion was filtered through a 300-mesh metal screen.

The residue was dried at 108° C. for 1 hour, and the mass (Y′) of the dried residue was measured.

Then, the gel fraction was determined on the basis of the expression [(Y′)/(X′)]×100 using the measured mass (X′) and mass (Y′).

### [Printing by Screen Printing Method]

Using the silver paste for screen printing, a straight line with a length of about 1 cm, a line width of 50 μm, and a film thickness of 1 μm was printed on the surfaces of three types of conductive-ink absorbing substrates prepared using the substrates (i), (ii), and (iii) with a screen plate that was a metal mesh 250. Then, drying was performed at 150° C. for 30 minutes to prepare printed items (conductive patterns).

In the conductive-ink absorbing substrates of Examples 1 to 9 and Comparative examples 1 to 3, a crosslinked structure was formed in the absorbing layer through the step of drying at 150° C. for 30 minutes subsequent to printing using the above-described ink.

### [Printing by Relief Reverse Printing Method]

The printing plate used was a line-shaped relief printing plate. The blanket used was T-60 (blanket, produced by KINYOSHA CO., LTD.). The above-described conductive ink was uniformly applied to the surface of the blanket using a bar coater, and the relief printing plate was pressed against the coated surface to transfer a portion of the deposited silver ink to the relief printing plate. Silver ink remaining on the surface of the blanket was then transferred to the surface of the absorbing layer constituting the conductive-ink absorbing substrate. Subsequently, drying was performed at 180° C. for 30 minutes. Thus, a conductive pattern having a line width of 20 μm and a film thickness of 0.5 μm was formed.

### [Printing by Gravure Offset Printing Method]

The printing plate used was an intaglio printing plate prepared by being etched in a line shape. The blanket used was T-60 (blanket, produced by KINYOSHA CO., LTD.). The above-described conductive ink was applied to the intaglio printing plate using a doctor blade, and a blanket cylinder including this blanket was pressed against the surface of the intaglio printing plate to transfer a portion of conductive ink deposited on the surface of the intaglio printing plate to the surface of the blanket. The surface of the blanket was then pressed against the surface of the absorbing layer constituting the conductive-ink absorbing substrate to transfer the deposited conductive ink to the surface of the absorbing layer. Subsequently, firing was performed at 120° C. for 30 minutes. Thus, a conductive pattern having a line width of 50 μm and a film thickness of 3 μm was formed.

[Method for Evaluating Characteristic of being Formed of Fine Lines (Presence or Absence of Line Bleeding)]

The entire printed portion (line portion) formed on the surface of the printed item (conductive pattern) prepared by the above-described method was observed with an optical microscope (digital microscope VHX-100, produced by Keyence Corporation) to inspect the printed portion for the presence of bleeding.

Specifically, an evaluation of “A” was given when no bleeding was observed at the edge of the printed portion (line portion), the boundary between the printed portion and the non-printed portion was clear, and no difference of height between the edge and the middle of the line portion was observed, that is, the entire line portion was smooth; an evaluation of “B” was given when, although a little bleeding was observed at a small part of the edge of the printed portion (line portion), the boundary between the printed portion and the non-printed portion was clear and the entire line portion was smooth; an evaluation of “C” was given when, although a little bleeding was observed at about ⅓ or less of the edge of the printed portion (line portion) and the boundary between the printed portion and the non-printed portion was not clear partially at the edge at which a little bleeding was observed, the entire line portion was smooth and it was possible to put it to use; an evaluation of “D” was given when, bleeding was observed at about ⅓ to ½ of the edge of the printed portion (line portion), the boundary between the printed portion and the non-printed portion was not clear partially at the edge at which bleeding was observed, and the difference of height between the edge and the middle of the line portion was observed, that is, the entire line portion was not smooth; and an evaluation of “E” was given when, bleeding was observed at about ½ or more of the edge of the printed portion (line portion), the boundary between the printed portion and the non-printed portion was not clear partially at the edge at which bleeding was observed, and the difference of height between the edge and the middle of the line portion was observed, that is, the entire line portion was not smooth.

### [Method for Evaluating Durability]

Using the nano-silver ink 1 for inkjet printing, a rectangular region (area) having a length of 3 cm, a width of 1 cm, and a film thickness of 0.5 μm was printed on the surface of a conductive-ink absorbing substrate prepared using the substrate (ii) with an inkjet printer (inkjet test machine: EB100, evaluation printer head: KM512L, ejection rate: 42 pl, produced by Konica Minolta IJ Technologies, Inc.). Then, drying was performed at 150° C. for 30 minutes to prepare a printed item (conductive pattern). In the conductive-ink absorbing substrates of Examples 1 to 9 and Comparative examples 1 to 3, a crosslinked structure was formed in the ink absorbing layer through the step of drying at 150° C. for 30 minutes subsequent to printing using the above-described ink.

A 3 cm×3 cm sample piece was cut from the printed item so that both the ink absorbing layer in the printed portion and the ink absorbing layer in the non-printed portion of the printed item (conductive pattern) could be observed. The sample piece was then immersed in a 5% by mass aqueous hydrochloric acid solution or a 5% by mass aqueous sodium hydroxide solution kept at 40° C. for 24 hours. Subsequently, the appearance of the sample piece was observed. Specifically, the appearance of the printed portion and non-printed portion of the printed item that was dried at a normal temperature after the immersion was visually inspected. An evaluation of [A] was given when no change in the appearance was observed; an evaluation of [B] was given when no change was observed in the printed portion and, although blushing was observed at a small part of the non-printed portion, the blushing was at an acceptable level for practical use; an evaluation of [C] was given when no change was observed in the printed portion but blushing was observed almost all over the non-printed portion; an evaluation of [D] was given when a portion of the ink absorbing layer constituting the printed portion and non-printed portion was dissolved and removed from the surface of the substrate; and an evaluation of [E] was given when a substantially half or more the ink absorbing layer constituting the printed portion and non-printed portion was dissolved and removed from the surface of the substrate.

### [Method for Evaluating Conductivity]

Using the nano-silver ink 1 for inkjet printing, a rectangular region (area) having a length of 3 cm, a width of 1 cm, and a film thickness of 0.5 μm was printed on the surfaces of two types of conductive-ink absorbing substrates prepared using the substrates (i) and (ii) with an inkjet printer (inkjet test machine: EB100, evaluation printer head: KM512L, ejection rate: 42 pl, produced by Konica Minolta IJ Technologies, Inc.). Then, drying was performed at 150° C. for 30 minutes to prepare printed items (conductive patterns). In the conductive-ink absorbing substrates of Examples 1 to 9 and Comparative examples 1 to 3, a crosslinked structure was formed in the ink absorbing layer through the step of drying at 150° C. for 30 minutes subsequent to printing using the above-described ink.

Using the silver paste for screen printing, a rectangular region (area) having a length of 3 cm, a width of 1 cm, and a film thickness of 1 μm was printed on the surfaces of two types of conductive-ink absorbing substrates prepared using the substrates (i) and (ii) with a screen plate that was a metal mesh 250. Then, drying was performed at 150° C. for 30 minutes to prepare printed items (conductive patterns).

The volume resistivity of the solid-printed portion, that is, the rectangular region having a length of 3 cm and a width of 1 cm formed on the surface of the printed item (conductive pattern) by the above-described method was measured with a LORESTA indicator (MCP-T610, produced by Mitsubishi Chemical Corporation). An evaluation of “A” was given when the volume resistivity was less than 5×10⁻⁶ Ω·cm; an evaluation of “B” was given when the volume resistivity was 5×10⁻⁶ or more and less than 9×10⁻⁶ Ω·cm and it was entirely possible to put it to use; an evaluation of “C” was given when the volume resistivity was 9×10⁻⁶ or more and less than 5×10⁻⁵ Ω·cm and it was possible to put it to use; an evaluation of “D” was given when the volume resistivity was 5×10⁻⁵ or more and less than 9×10⁻⁵ Ω·cm; and an evaluation of “E” was given when the volume resistivity was 9×10⁻⁵ or more and it was difficult to put it to practical use.

TABLE 3

| | | Example | | | | | | |
|---|---|---|---|---|---|---|---|---|
| | | — | 1 | 2 | 3 | 4 | 5 | 6 |
| Gel fraction | | — | 65 | 66 | 70 | 60 | 45 | 40 |
| (after heating at 70° C.; mass %) | | | | | | | | |
| Gel fraction | | — | 100 | 100 | 99 | 99 | 98 | 96 |
| (after heating at 150° C.; mass %) | | | | | | | | |
| Characteristic | Nano-silver ink 1 for | PET | A | A | B | A | A | A |
| of being | inkjet printing | PI | A | A | B | A | A | A |
| formed of | | PEN | A | A | B | A | A | A |
| fine lines | Nano-silver ink 2 for | PET | A | A | A | A | B | B |
| | inkjet printing | PI | A | A | A | A | B | B |
| | | PEN | A | A | A | A | B | B |
| | Nano-silver ink 3 for | PET | B | B | B | B | C | C |
| | inkjet printing | PI | B | B | B | B | C | C |
| | | PEN | B | B | B | B | C | C |
| | Silver paste for | PET | A | A | A | A | B | B |
| | screen printing | PI | A | A | A | A | B | B |
| | | PEN | A | A | A | A | B | B |
| | Silver ink for relief | PET | A | A | A | A | B | B |
| | reverse printing | | | | | | | |
| | Silver ink for gravure | PET | A | A | A | A | B | B |
| | offset printing | | | | | | | |
| Durability | 5% by mass aqueous | PI | A | B | A | B | B | A |
| | hydrochloric acid | | | | | | | |
| | solution | | | | | | | |
| | 5% by mass aqueous | PI | A | B | A | B | B | A |
| | sodium hydroxide | | | | | | | |
| | solution | | | | | | | |
| Conductivity | Nano-silver ink 1 for | PET | A | A | B | A | A | A |
| | inkjet printing | PI | A | A | B | A | A | A |
| | Silver paste for | PET | A | A | A | A | B | B |
| | screen printing | PI | A | A | A | A | B | B |
| | Silver ink for relief | PET | A | A | A | A | B | B |
| | reverse printing | | | | | | | |
| | Silver ink for gravure | PET | A | A | A | A | B | B |
| | offset printing | | | | | | | |

TABLE 4

| | | | | | | Comparative | | |
|---|---|---|---|---|---|---|---|---|
| | | | Example | | | example | | |
| | | | 7 | 8 | 9 | 1 | 2 | 3 |
| Gel fraction | | — | 50 | 68 | 20 | 40 | 30 | 40 |
| (after heating at 70° C.; mass %) | | | | | | | | |
| Gel fraction | | — | 98 | 97 | 95 | 90 | 85 | 45 |
| (after heating at 150° C.; mass %) | | | | | | | | |
| Characteristic | Nano-silver ink 1 for | PET | B | B | B | E | D | A |
| of being | inkjet printing | PI | B | B | B | E | E | A |
| formed of | | PEN | B | B | B | E | E | A |
| fine lines | Nano-silver ink 2 for | PET | C | C | A | E | D | A |
| | inkjet printing | PI | C | C | A | E | E | A |
| | | PEN | C | C | A | E | E | A |
| | Nano-silver ink 3 for | PET | B | B | C | E | D | B |
| | inkjet printing | PI | B | B | C | E | E | B |
| | | PEN | B | B | C | E | E | B |
| | Silver paste for | PET | B | B | B | E | D | A |
| | screen printing | PI | B | B | B | E | E | A |
| | | PEN | B | B | B | E | E | A |
| | Silver ink for relief | PET | B | B | B | E | D | A |
| | reverse printing | | | | | | | |
| | Silver ink for gravure | PET | B | B | B | E | D | A |
| | offset printing | | | | | | | |
| Durability | 5% by mass aqueous | PI | B | B | B | D | D | E |
| | hydrochloric acid | | | | | | | |
| | solution | | | | | | | |
| | 5% by mass aqueous | PI | B | B | B | D | D | E |
| | sodium hydroxide | | | | | | | |
| | solution | | | | | | | |
| Conductivity | Nano-silver ink 1 for | PET | B | B | B | E | D | A |
| | inkjet printing | PI | B | B | B | E | E | A |
| | Silver paste for | PET | B | B | C | D | D | A |
| | screen printing | PI | B | B | C | D | E | A |
| | Silver ink for relief | PET | B | B | C | D | D | A |
| | reverse printing | | | | | | | |
| | Silver ink for gravure | PET | B | B | C | D | D | A |
| | offset printing | | | | | | | |

The conductive patterns prepared in Examples 1 and 2 had an excellent characteristic of being formed of fine lines, excellent durability, and excellent conductivity.

The conductive pattern prepared in Example 3, which differed from the conductive pattern prepared in Example 1 in terms of the amount of N-butoxymethyl(meth)acrylamide used, had an excellent characteristic of being formed of fine lines, excellent durability, and good conductivity.

The conductive pattern of Example 4, which was prepared using N-isobutoxymethyl(meth)acrylamide instead of N-butoxymethyl(meth)acrylamide, had an excellent characteristic of being formed of fine lines, excellent conductivity, and good durability.

The conductive patterns of Examples 5 and 6, which were prepared using a crosslinking agent in combination with a vinyl resin, despite showing a small degradation of the characteristic of being formed of fine lines when a specific conductive ink was used, had a good characteristic of being formed of fine lines, good durability, and good conductivity.

The conductive patterns of Examples 7 and 9, in which a large amount of methyl methacrylate was used, and the conductive pattern of Example 8, in which a small amount of methyl methacrylate was used, despite showing small degradations of the characteristic of being formed of fine lines and durability, had a good characteristic of being formed of fine lines, good durability, and good conductivity.

On the other hand, the conductive patterns of Comparative examples 1 and 2, in which the content of methyl methacrylate used did not fall within the predetermined range of the content of methyl methacrylate, had degraded characteristic of being formed of fine lines, durability, and conductivity that were insufficient for practical use, despite including an absorbing layer in which a crosslinked structure was formed.

The conductive pattern of Comparative example 3, in which a predetermined amount of methyl methacrylate was used but no crosslinked structure was formed, had significantly degraded durability while having an excellent characteristic of being formed of fine lines and excellent conductivity.

1. A conductive pattern comprising:
a layer (A) including a substrate;
an absorbing layer (B); and
a conductive layer (C),
wherein the absorbing layer (B) is formed by applying conductive ink containing a conductive substance (c) that constitutes the conductive layer (C) to a surface of a resin layer (B1), which includes a vinyl resin (b1) produced by polymerizing a vinyl monomer mixture containing 10% by mass to 70% by mass of methylmethacrylate, and subsequently forming crosslinks in the resin layer (B1).

2. The conductive pattern according to claim 1, wherein the vinyl resin (b1) includes a crosslinkable functional group.

3. The conductive pattern according to claim 2, wherein the crosslinkable functional group is capable of causing a crosslinking reaction when heated to 100° C. or more to form a crosslinked structure.

4. The conductive pattern according to claim 3, wherein the crosslinkable functional group is at least one thermal-crosslinkable functional group selected from the group consisting of a methylolamide group and an alkoxymethylamide group.

5. The conductive pattern according to claim 1, wherein the resin layer (B1) includes the vinyl resin (b1) and a crosslinking agent (b2).

6. The conductive pattern according to claim 5, wherein the crosslinking agent (b2) is capable of causing a crosslinking reaction when heated to 100° C. or more to form a crosslinked structure.

7. The conductive pattern according to claim 5, wherein the crosslinking agent (b2) is at least one thermal crosslinking agent selected from the group consisting of melamine compounds, epoxy compounds, blocked isocyanate compounds, oxazoline compounds, and carbodiimide compounds.

8. The conductive pattern according to claim 1, wherein the conductive ink is applied by an inkjet printing method, a screen printing method, a relief reverse printing method, or a gravure offset printing method.

9. An electric circuit comprising the conductive pattern according to claim 1.

10. A method for producing a conductive pattern that includes a layer (A) including a substrate, an absorbing layer (B), and a conductive layer (C), the method comprising:
forming a resin layer (B1) by applying a resin composition for forming an absorbing layer to a portion or the entirety of a surface of the substrate and drying the resin composition, wherein the resin composition includes a vinyl resin (b1) produced by polymerizing a monomer mixture containing 10% by mass to 70% by mass of methylmethacrylate;
subsequently applying conductive ink containing a conductive substance (c) to a portion or the entirety of a surface of the resin layer (B1); and
heating the resin layer (B1) to cause a crosslinking reaction and thereby forming the absorbing layer (B) having a crosslinked structure.

11. The conductive pattern according to claim 5, wherein the conductive ink is applied by an inkjet printing method, a screen printing method, a relief reverse printing method, or a gravure offset printing method.
